(19) United States
(12) Patent Application Publication
(10) Pub. No.: US 2015/0015129 A1
(43) Pub. Date: Jan. 15, 2015

(54) BEZEL ASSEMBLY OF ELECTRONIC DEVICE ENCLOSURE

(71) Applicants: HONG FU JIN PRECISION INDUSTRY (WUHAN) CO., LTD., Wuhan (CN); HON HAI PRECISION INDUSTRY CO., LTD., New Taipei (TW)

(72) Inventors: LIN DING, Wuhan (CN); CONG TANG, Wuhan (CN); YU-MING XIAO, Wuhan (CN)

(21) Appl. No.: 14/327,773

(22) Filed: Jul. 10, 2014

(30) Foreign Application Priority Data
Jul. 12, 2013 (CN) 2013102914510

(51) Int. Cl. H05K 7/14; H05K 5/02

(52) U.S. Cl. CPC H05K 7/1438; H05K 5/0217; H05K 5/0221; H05K 7/14
USPC 312/223.1

(57) ABSTRACT

A fastener-free bezel assembly includes a panel and a bracket. The panel includes a front plate defining two stopping holes and a resilient piece extending from the front plate and defining a latching gap. The bracket includes two side plates and two latching hooks, and a blocking tab extends from one of the two side plates with a protrusion. Each latching hook is received in each stopping hole, and the bracket is movable to engage each latching hook with the front plate, preventing the bracket from moving in a plane substantially perpendicular to the front plate. The protrusion engages in the latching gap, preventing the bracket from moving perpendicular to the first plane. The resilient piece deforms to disengage the protrusion from the latching gap.

### CROSS-REFERENCE TO RELATED APPLICATIONS

This application claims priority to China Patent Application No. 20131029145.0 filed on Jul. 12, 2013 in the China Intellectual Property Office, the contents of which are hereby incorporated by reference.

### FIELD

The present disclosure relates to electronic device enclosures, more particularly to a bezel assembly of an electronic device enclosure.

### BACKGROUND

A plurality of input/output (10) interfaces are usually secured to a bracket, and then the bracket may be attached to a panel of a computer enclosure with screws. A tool, such as a screwdriver, may be used to fasten or unfasten the screws when the bracket is assembled or disassembled. The assembly and disassembly of the bracket is laborious and time-consuming.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, perspective view of a bezel assembly in accordance with an embodiment.

FIG. 2 is similar to FIG. 1, but showing the bezel assembly from another angle.

FIG. 3 is an assembled view of the bezel assembly of FIG. 1, and the bracket is in a first position.

FIG. 4 is similar to FIG. 3, but showing the bezel assembly from another angle.

FIG. 5 is another assembled view of the bezel assembly of FIG. 1, the bracket being in a second position.

### DETAILED DESCRIPTION

The bezel assembly is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

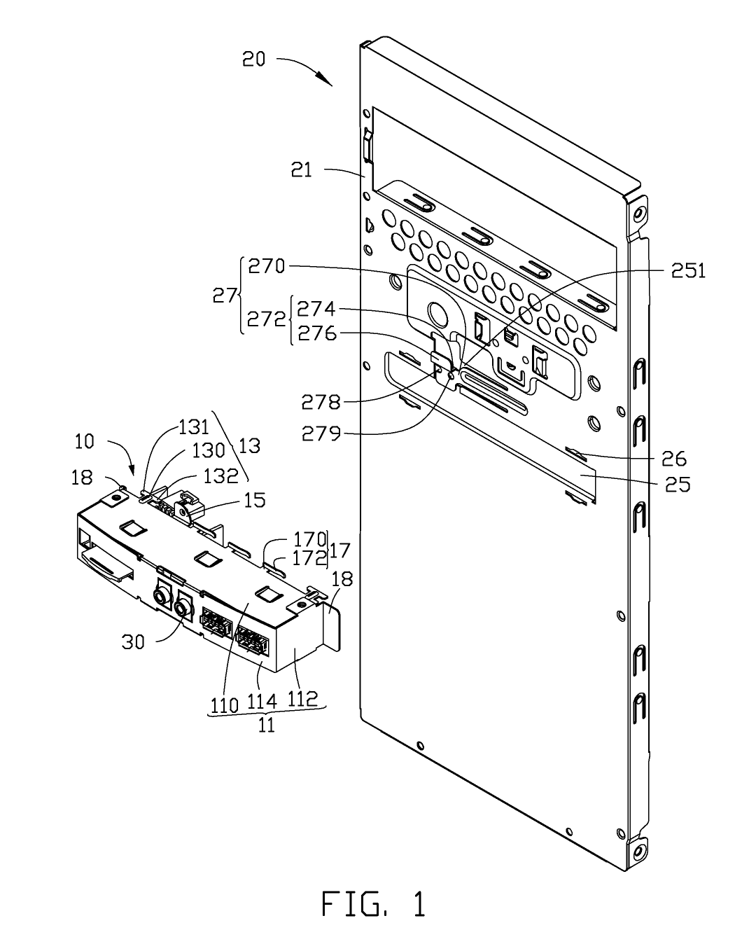

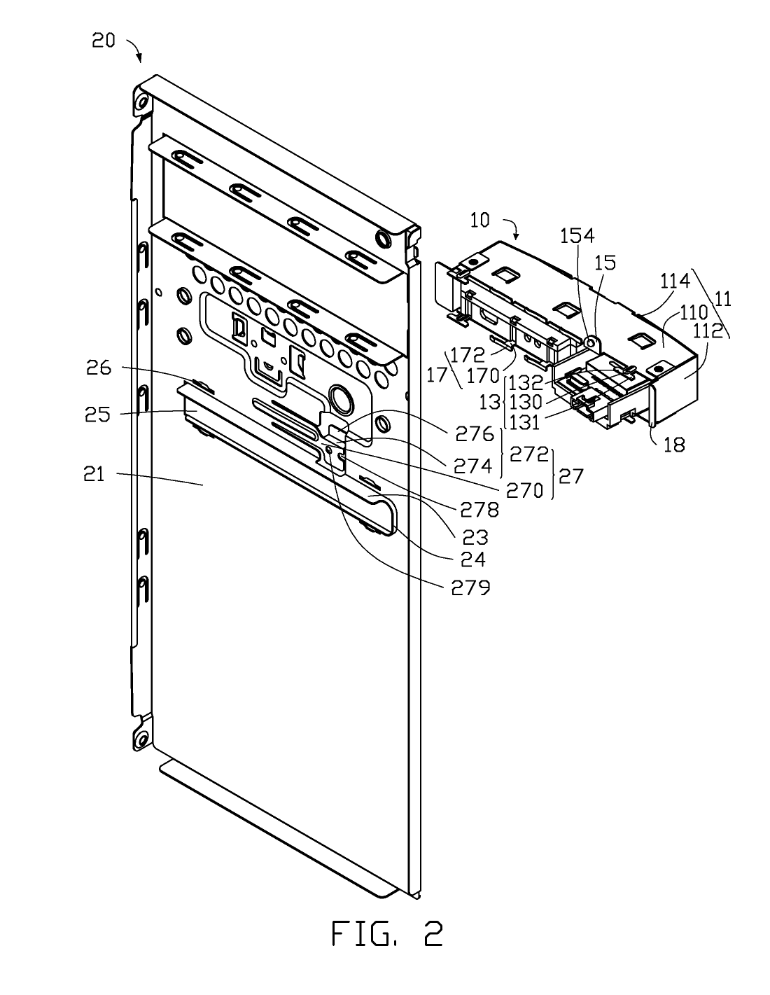

FIGS. 1-2 illustrate a bezel assembly in accordance with an embodiment. The bezel assembly includes a bracket 10 and a panel 20. In one embodiment, the panel 20 is a shielding panel of a computer case. A plurality of input/output (10) interfaces 30 are secured to the bracket 10.

The panel 20 includes a front plate 21. The front plate 21 defines an installation opening 25 through the bracket 10, and a cutout 251 is defined in the front plate 21, communicating with the installation opening 25. Four stopping holes 26 are defined in the front plate 21, arranged at four corners of a first rectangle. Two of the four stopping holes 26 are positioned on a top side of the installation opening 25, and the other two of the four stopping holes 26 are positioned on a bottom side of the installation opening 25.

Two first flanges 23 and two second flanges 24 are located on the front plate 21. The two first flanges 23 are parallel to each other and perpendicularly extend backwards from opposite edges of the installation openings 25. The two second flanges 24 extend from the other opposite edges of the installation opening 25 and are connected to the two first flanges 23.

A resilient portion 27 extends from the front plate 21 and is located in the cutout 251. The resilient portion 27 includes a resilient piece 270 and an operation piece 272. The resilient piece 270 extends from one edge of the cutout 251 towards opposite edge of the cutout 251. The resilient piece 270 has the same plane as the front plate 21 and defines a latching gap 278 and a latching hole 279 positioned below the operation piece 272. The latching gap 278 and the latching hole 279 are arranged at a long side of the first rectangle. The operation piece 272 includes a connecting tab 274 and an operation tab 276. The connecting tab 274 extends outwards from a top edge of the resilient piece 270. The operation tab 272 extends upwards from a free end of the connecting tab 274.

FIG. 1 shows the bracket 10 including two side plates 110, a front wall 114 connected to the top wall 110 and the bottom wall 111, and two sidewalls 112. The two side plates 110 are parallel to each other. The front wall 114 is connected to the two side plates 110. The two sidewalls 112 are respectively connected to the two side plates 110. The plurality of connectors 30 is installed on the front wall 114.

Two latching hooks 13 extend from each of the two side plates 110. The latching hooks 13 are arranged at four corners of a second rectangle and correspond to the four stopping holes 26. Each latching hook 13 includes a linking tab 130, a first latching tab 131, and a second latching tab 132. The linking tab 130 extends towards the panel 20 from a side plate 110. The first latching tab 131 and the second latching tab 132 are located in a distal end of the linking tab 130 and extend in opposite directions from the linking tab 130. The extension direction of each first latching tab 131 and each second latching tab 132 is substantially perpendicular to the two sidewalls 112 and parallel to the front plate 21. In one embodiment, each latching hook 13 is substantially T-shaped. A blocking tab 15 substantially perpendicularly extends upwards from one of the side plates 110 and is located between adjacent latching hooks 13. In one embodiment, the blocking tab 15 is substantially parallel to the front plate 21. A protrusion 154 protrudes from the blocking tab 15 corresponding to the latching hole 279.

A plurality of limiting legs 17 is located on each of the two side plates 110, and each limiting leg 17 includes a limiting tab 170 and an abutting tab 172. The limiting tab 170 extends from a corresponding side plate 110, and the abutting tab 172 is positioned on a distal end of the limiting tab 170. The abutting tab 172 is substantially parallel to the front plate 21. A limiting piece 18 substantially perpendicularly extends from each of the two sidewalls 112.

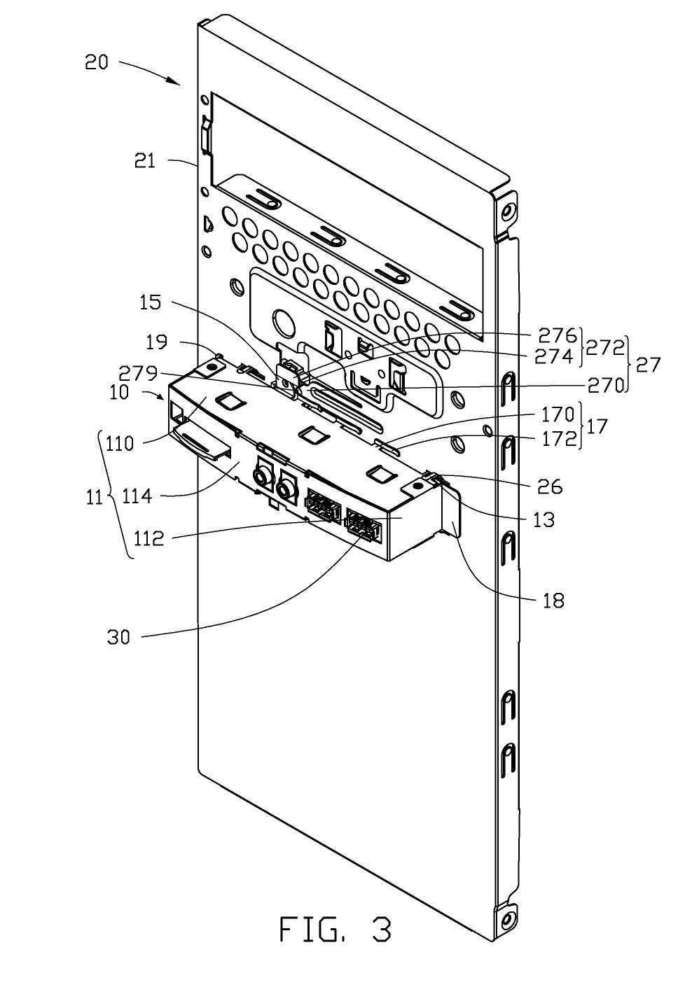

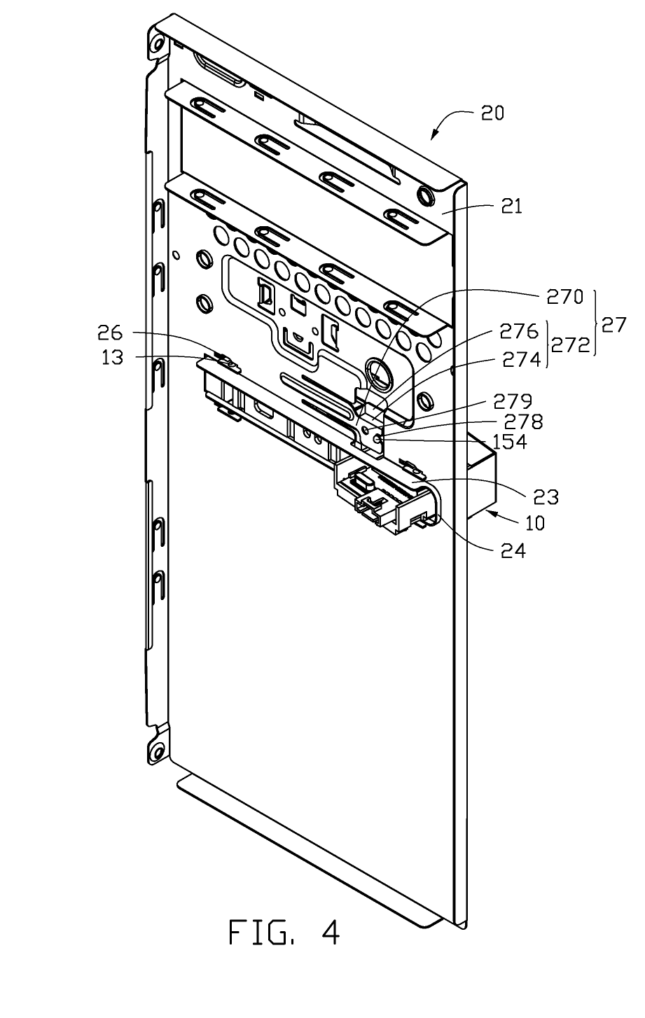

FIGS. 3-5 illustrate that, in assembly, a part of the bracket 10 is inserted into the installation opening 25 to abut the first flanges 24. Each latching hook 18 extends through each stopping hole 26, and the protrusion 154 of the blocking tab 15 resists the resilient pieces 270. The plurality of limiting legs 17 and the limiting pieces 18 are against the front plate 21. The bracket 10 is moved along a first direction perpendicular to the two sidewalls 112 until the bracket 10 is located in a first position (shown in FIG. 3), where the first latching tab 131 of each latching hook 13 engages with the front plate 21, to prevent the bracket 10 from moving in a first plane that is perpendicular to the front plate 21. The protrusion 154 engages in the latching gap 278, to prevent the bracket 10 from moving in a second plane that is parallel to the front plate 21.

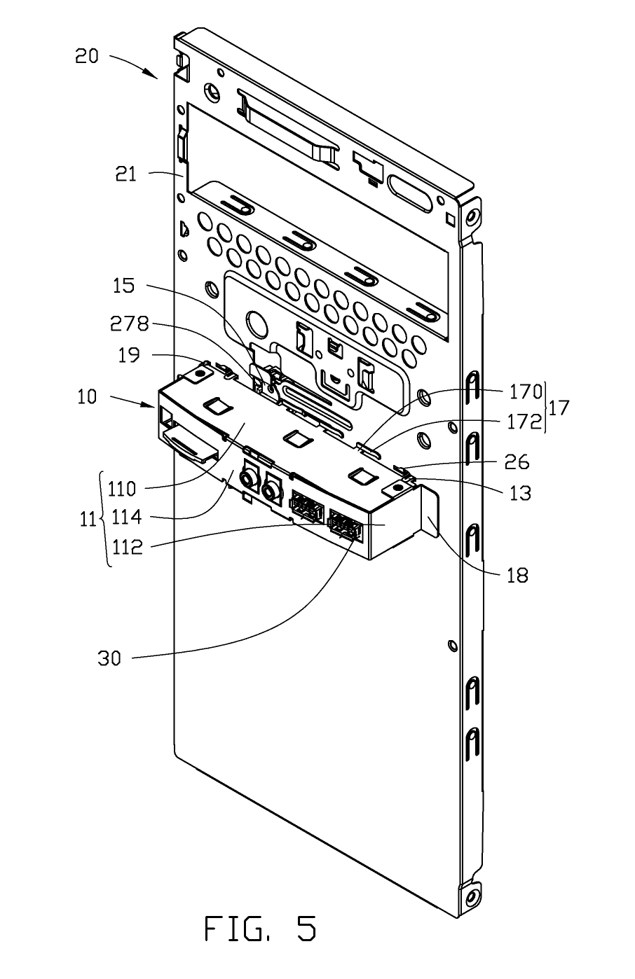

When adjusting a position of the bracket 10 relative to the panel 20, the operation piece 272 is actuated to deform the resilient piece 270, and the protrusion 154 is disengaged from the latching gap 278. At the same time, the bracket 10 is moved along a second direction opposite to the first direction, until the bracket 10 is located in a second position (shown in FIG. 5), where the protrusion 154 is aligned with the latching hole 279, and the second latching tab 132 of each latching hook 13 is engaged with the front plate 21, to prevent the bracket 10 from moving in the first plane. When the pressure of the operation is released, the resilient piece 270 resiliently rebounds to engage the protrusion 154 in the latching hole 279, to prevent the bracket 10 from moving in the second plane.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A bezel assembly, comprising:
a panel comprising a front plate and a resilient piece, the front plate defining two stopping holes, and the resilient piece extending from the front plate and defining a latching gap; and
a bracket comprising two side plates parallel to each other and two latching hooks, each of the two latching hooks extending from each of the two side plates, and a blocking tab extending from one of the two side plates and having a protrusion;
wherein each of the two latching hooks is received in each of the two stopping holes, and the bracket is movable relative to the front plate along a first direction to engage each of the two latching hooks with the front plate, for preventing the bracket from moving in a first plane that is substantially perpendicular to the front plate; the protrusion is engaged in the latching gap, to prevent the bracket from moving in a second plane that is perpendicular to the first plane; and the resilient piece is resiliently deformable to disengage the protrusion from the latching gap.

2. The bezel assembly of claim 1, wherein the resilient piece further defines a latching hole, and the bracket is movable along a second direction opposite to the first direction to engage the protrusion with the latching hole.

3. The bezel assembly of claim 2, wherein the two latching hooks are arranged at two ends of a diagonal line of a rectangle.

4. The bezel assembly of claim 3, wherein the latching gap and the latching hole are arranged at a long side of the rectangle.

5. The bezel assembly of claim 2, wherein each of the two latching hooks comprises a linking tab, a first latching tab, and a second latching tab, the linking tab of each of the two latching hooks is located in each of the two stopping holes, the bracket is movable along the first direction to engage the first latching tab with the front plate, and along the second direction to engage the second latching tab with the front plate.

6. The bezel assembly of claim 5, wherein the linking tab extends from a corresponding side plate, the first latching tab and the second latching tab extend from the linking tab and toward an opposite direction.

7. The bezel assembly of claim 1, wherein the blocking tab is substantially parallel to the resilient piece.

8. The bezel assembly of claim 1, wherein the front plate defines an installation opening for receiving the bracket, a cutout is defined in the front plate and in communication with the installation opening, and the resilient piece extends from one edge of the cutout and towards opposite edge of the cutout.

9. The bezel assembly of claim 8, wherein the resilient piece is positioned in the same plane with the front plate.

10. The bezel assembly of claim 8, wherein a plurality of limiting legs is located on each of the two side plates, and the plurality of limiting legs abuts the front plate.

11. A bezel assembly comprising:
a panel comprising a front plate and a resilient piece, the front plate defining four stopping holes, and the resilient piece extending from the front plate and defining a latching gap and a latching hole; and
a bracket comprising two side plates parallel to each other and four latching hooks, each of the four latching hooks extending from each of the two side plates, and a blocking tab extending from one of the two side plates and having a protrusion;
wherein the bracket is movable relative to the front plate between a first position and a second position when the resilient piece is resiliently deformed, in the first position, each of the four latching hooks extends through each of the four stopping holes to be engaged with the front plate, and the protrusion is engaged in the latching cutout; in the second position, each of the four latching hooks extends through each of the four stopping holes to be engaged with the front plate, and the protrusion is engaged in the latching cutout.

12. The bezel assembly of claim 11, wherein the four latching hooks are arranged at four corners of a rectangle.

13. The bezel assembly of claim 12, wherein the latching gap and the latching hole are arranged at a long side of the rectangle.

14. The bezel assembly of claim 11, wherein each of the four latching hooks comprises a linking tab, a first latching tab, and a second latching tab, the linking tab of each of the four latching hooks is located in each of the four stopping holes; in the first position, the first latching tab of each of the four latching hooks extends through each of the four stopping holes to be engaged with the front plate; in the second position, the second latching tab of each of the four latching hooks extends through each of the four stopping holes to be engaged with the front plate, and the protrusion is engaged in the latching cutout.

15. The bezel assembly of claim 14, wherein the linking tab extends from a corresponding side plate, the first latching tab and the second latching tab extend from the linking tab and towards an opposite direction.

16. The bezel assembly of claim 11, wherein the blocking tab is substantially parallel to the resilient piece.

17. The bezel assembly of claim 11, wherein the front plate defines an installation opening for receiving the bracket, a cutout is defined in the front plate and in communication with the installation opening, and the resilient piece extends from one edge of the cutout and towards an opposite edge of the cutout.

18. The bezel assembly of claim 17, wherein the resilient piece is in the same plane as the front plate.

19. The bezel assembly of claim 11, wherein a plurality of limiting legs is located on each of the two side plates, and the plurality of limiting legs abuts the front plate.

20. The bezel assembly of claim 11, wherein each of the plurality of limiting legs comprises a limiting tab and an abutting tab extending from the limiting tab, the abutting tab abuts the front plate.
